(19) United States
(12) Patent Application Publication
(10) Pub. No.: US 2009/0087548 A1
(43) Pub. Date: Apr. 2, 2009

(54) Method of forming circuit pattern

(75) Inventors: Young-Jae Kim, Suwon-si (KR); Jae-Woo Joung, Suwon-si (KR); Young-Seuck Yoo, Seoul (KR); Chang-Sung Park, Suwon-si (KR); Won-Chul Sim, Seongnam-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/007,978

(22) Filed: Jan. 17, 2008

(30) Foreign Application Priority Data
Sep. 28, 2007 (KR) 10-2007-0098389

(51) Int. Cl. H05K 3/12

(52) U.S. Cl. 427/98.4

(57) ABSTRACT

A method of forming a circuit pattern is disclosed. The method of forming a circuit pattern may include providing a substrate that has a porous layer formed on one side, ejecting a thermosetting metal ink using an inkjet head into the porous layer in correspondence to a circuit pattern, and applying heat to the ink and the porous layer to cure the ink and remove the porous layer. With this method, a fine-line circuit pattern can be implemented, and a desired thickness of the circuit pattern can be obtained, by using a porous layer in printing and by applying heat to cure the ink and remove the coating layer.

### CROSS-REFERENCE TO RELATED APPLICATIONS

This application claims the benefit of Korean Patent Application No. 10-2007-0098389 filed with the Korean Intellectual Property Office on Sep. 28, 2007, the disclosure of which is incorporated herein by reference in its entirety.

### BACKGROUND

1. Technical Field

The present invention relates to a method of forming a circuit pattern.

2. Description of the Related Art

Recent times have seen continued attempts to apply inkjet technology to various fields of art, such as in biochips, metal wiring in PCB's, and color patterns in LCD's, etc. In thus applying inkjet technology to new fields, situations may occur in which metal nanoparticles or high-viscosity polymers, etc., are ejected onto a substrate made of a special material, unlike the prior art of discharging low-viscosity ink drops onto paper to form letters or images.

It can be very difficult to increase the thickness of a pattern, in techniques that employ inkjet technology to form wiring. While it is possible to simply perform the printing a multiple number of times, this can lead to very long process times, and there is a risk of the wiring spreading to the sides so that the result is different from the desired pattern.

FIG. 1 is a process diagram illustrating a method of forming a circuit pattern according to the related art. In the related art, a metal wiring pattern 5 may be formed, as illustrated in FIG. 1, by preparing a substrate 1, performing surface modification such as of fluorine-based or plasma treatment, etc., to form a coating layer 2, and then ejecting metal ink 4 using an inkjet head 3.

The metal ink thus formed has a very low thickness, of 1 μm or less, so a desired thickness of the wiring pattern 5 can be obtained by repeated printing, etc. After repeating the printing until a desired thickness is obtained for the wiring pattern, drying and curing processes can be performed to form a conductive wiring pattern 5.

However, the method described above can be very time-consuming and can increase defect rate, since having to perform the printing several times leads to a greater likelihood of printing errors and to a risk of the wiring pattern 5 spreading.

### SUMMARY

An aspect of the invention is to provide a method of forming a circuit pattern, by which a fine-line circuit pattern can be implemented, and a desired thickness of the circuit pattern can be obtained, using a porous layer.

One aspect of the invention can provide a method of forming a circuit pattern that includes providing a substrate that has a porous layer formed on one side, ejecting a thermosetting metal ink using an inkjet head into the porous layer in correspondence to a circuit pattern, and applying heat to the ink and the porous layer to cure the ink and remove the porous layer.

The porous layer can be made of an organic material, and the thickness of the porous layer may be in correspondence with the thickness of the circuit pattern.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a process diagram illustrating a method of forming a circuit pattern according to prior art.

FIG. 2 is a flowchart illustrating a method of forming a circuit pattern according to an aspect of the present invention.

FIG. 3, FIG. 4, FIG. 5, and FIG. 6 represent a flow diagram illustrating the method of forming a circuit pattern shown in FIG. 2.

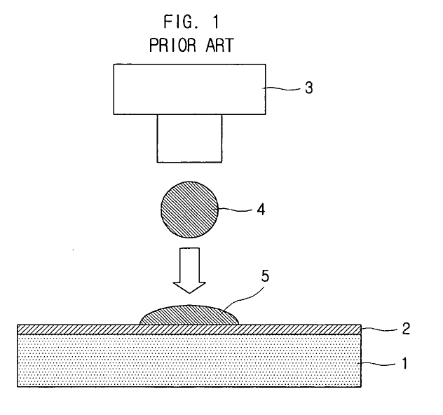

### DETAILED DESCRIPTION

As the invention allows for various changes and numerous embodiments, particular embodiments will be illustrated in drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

The terms used in the present application are merely used to describe particular embodiments, and are not intended to limit the present invention. An expression used in the singular encompasses the expression of the plural, unless it has a clearly different meaning in the context. In the present application, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Embodiments of the invention will be described below in more detail with reference to the accompanying drawings, in which those components are rendered the same reference numeral that are the same or are in correspondence, regardless of the figure number, and redundant explanations are omitted.

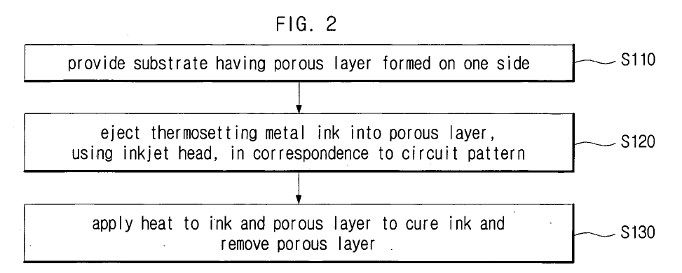

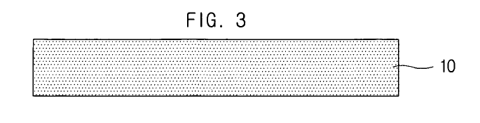

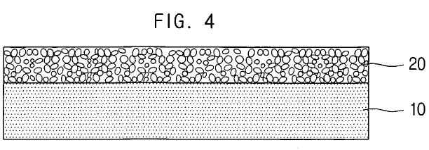

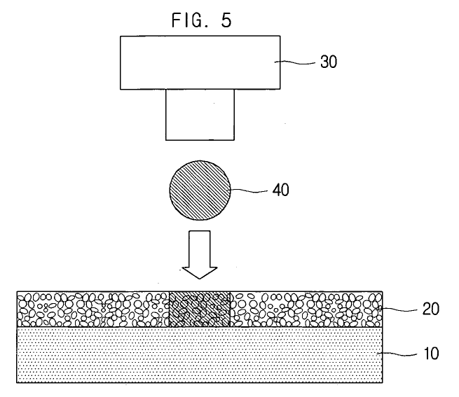

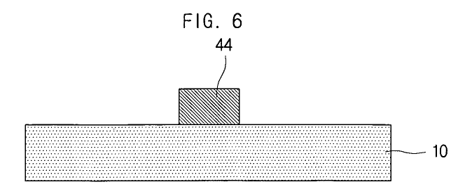

FIG. 2 is a flowchart illustrating a method of forming a circuit pattern according to an aspect of the present invention, and FIGS. 3 to 6 represent a flow diagram illustrating the method of forming a circuit pattern shown in FIG. 2. In FIGS. 3 to 6 are illustrated a substrate 10, a porous layer 20, an inkjet head 30, metal ink 40, and a circuit pattern 44.

First, a substrate 10 may be provided that has a porous layer 20 formed on one side (S110). For this, an operation may be performed of coating a porous material on one side of a substrate 10 such as that illustrated in FIG. 3, or a substrate 10 may be used that already has a porous layer 20 formed thereon. A substrate 10 having a porous layer 20 formed on one side is illustrated in FIG. 4.

Next, as illustrated in FIG. 5, a thermosetting metal ink 40 may be ejected into the porous layer 20, to correspond with the circuit pattern 44, using an inkjet head 30. When the metal ink 40 is ejected into the porous layer 20, the ejected metal ink 40 can be absorbed by the porous layer 20, so that the ejected metal ink 40 can be prevented from spreading excessively, and consequently a fine-line circuit pattern 44 can be formed. Moreover, since the ejected metal ink 40 does not spread excessively, a sufficient thickness can be obtained for the circuit pattern 44.

In order to form the circuit pattern 44 to a desired thickness, the porous layer 20 can be used which has a thickness corresponding to the thickness of the final circuit pattern 44. As illustrated in FIG. 5, when the metal ink 40 is ejected to a sufficient degree in the porous layer 20 corresponding to the thickness of the final circuit pattern 44, the portion of the porous layer 20 to which the metal ink 40 is ejected can be completely filled with the metal ink 40, after which curing the filled ink 40 may provide a circuit pattern 44 of a desired thickness.

For example, a porous layer can be used that has the same thickness as that of the desired final circuit pattern 44, or a porous layer can be used that has a slightly greater thickness, in consideration of the shrinkage that may occur during the curing process.

After thus ejecting the metal ink 40, heat may be applied to the metal ink 40 and the porous layer 20 to cure the metal ink 40 and remove the porous layer 20 (S130). That is, the metal ink 40 in a paste-like state can be cured to form a conductive circuit pattern 44. For this, a thermosetting metal ink 40 may be used.

This particular embodiment presents a method of removing the porous layer 20 at the same time the metal ink 40 is cured. In other words, the curing of the metal ink 40 and the removing of the porous layer 20 can be performed in a single process.

In order that such a process may be performed efficiently, a porous layer 20 made of an organic material may be used. In the process of increasing the temperature to about 300° C. for curing the metal ink 40, most of the porous layer 20 can be oxidized and removed. The circuit pattern 44 formed on one side of the substrate 10, formed as an outcome of such a process, is illustrated in FIG. 6.

As set forth in certain embodiments of the invention described above, a fine-line circuit pattern can be implemented, and a desired thickness of the circuit pattern can be obtained, by using a porous layer in printing and by applying heat to cure the ink and remove the coating layer.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

Many embodiments are encompassed by the claims of the present invention, besides those set forth above.

What is claimed is:

1. A method of forming a circuit pattern, the method comprising:
providing a substrate, the substrate having a porous layer on one side thereof;
ejecting a thermosetting metal ink into the porous layer in correspondence to a circuit pattern using an inkjet head; and
applying heat to the ink and the porous layer to cure the ink and remove the porous layer.

2. The method of claim 1, wherein the porous layer is made of an organic material.

3. The method of claim 1, wherein a thickness of the porous layer is in correspondence with a thickness of the circuit pattern.
